(19) United States
(12) Patent Application Publication
(10) Pub. No.: US 2026/0018517 A1
(43) Pub. Date: Jan. 15, 2026

(54) SELF-ALIGNED BOTTOM DIELECTRIC ISOLATION FOR BACKSIDE POWER DELIVERY

(71) Applicant: Applied Materials, Inc., Santa Clara, CA (US)

(72) Inventor: Byeong Chan LEE, San Jose, CA (US)

(21) Appl. No.: 18/771,056

(22) Filed: Jul. 12, 2024

(51) Int. Cl. H01L 23/528; H01L 29/06; H01L 29/08; H01L 29/423; H01L 29/49; H01L 29/66; H01L 29/775; H01L 29/786

(52) U.S. Cl. CPC H01L 23/5286; H10D 30/014; H10D 30/43; H10D 30/6735; H10D 30/6739; H10D 30/6757; H10D 62/121; H10D 62/151; H10D 64/017

(57) ABSTRACT

A method of forming a portion of a gate-all-around field-effect transistor (GAA FET). includes forming a bottom source/drain (S/D) recess through fin-shaped columns from a top S/D recess into a substrate, wherein each of the fin-shaped columns comprises a bottom high germanium (Ge) layer on the substrate and a stack of alternating channel layers and sacrificial layers over the bottom high Ge layer, forming an S/D epitaxial (epi) layer within the bottom S/D recess, selectively removing the bottom high Ge layer to the sacrificial layers, and forming a bottom cavity between the substrate and the stack of alternating channel layers and sacrificial layers, and forming a bottom dielectric layer in the bottom cavity.

### BACKGROUND

### Field

Embodiments described herein generally relate to semiconductor device fabrication, and more particularly, to forming electrical contacts and isolation modules for back-side power delivery.

### Description of the Related Art

Traditionally, chips are constructed with transistors on a front side of a silicon wafer and all interconnects that power them and transmit their data signals built above them, i.e., to deliver power on the front side of a chip. One of the key technologies to enable scaling below 3 nm involves delivering of power on a back side of a chip. This back-side power delivery eliminates the need to share interconnect resources between signals and power lines on a front side of the chip as power is moved to the back side of the chip. Backside power delivery further eliminates the need for a power delivery track from lower layer front side interconnects, leading to cost savings. Backside power delivery also allows different metal layers to be optimally fabricated, such as wider lines for an operating voltage V_{dd} and a common ground voltage Vₛₛ, and thinner lines to carry signals.

However, back-side power delivery creates new challenges, such as patterning electrical contact features and forming isolation modules on a back side of a chip without impacting performance of transistors on a front side of the chip.

Therefore, there is a need for methods for overcoming such challenges in back-side power delivery.

### SUMMARY

Embodiments of the present disclosure provide a method of forming a portion of a gate-all-around field-effect transistor (GAA FET). The method includes forming a bottom source/drain (S/D) recess through fin-shaped columns from a top S/D recess into a substrate, wherein each of the fin-shaped columns comprises a bottom high germanium (Ge) layer on the substrate and a stack of alternating channel layers and sacrificial layers over the bottom high Ge layer, forming an S/D epitaxial (epi) layer within the bottom S/D recess, selectively removing the bottom high Ge layer to the sacrificial layers, and forming a bottom cavity between the substrate and the stack of alternating channel layers and sacrificial layers, and forming a bottom dielectric layer in the bottom cavity.

Embodiments of the present disclosure also provide a method of forming a bottom source/drain (S/D) recess through fin-shaped columns from a top S/D recess into a substrate, wherein each of the fin-shaped column comprises a bottom silicon germanium (SiGe) layer on the substrate and a stack of alternating channel layers and sacrificial layers over the bottom SiGe layer, forming an S/D epitaxial (epi) layer within the bottom S/D recess, selectively removing the sacrificial layers and the bottom SiGe layer to the channel layers, and forming metal gate cavities between adjacent channel layers, and a bottom cavity between the substrate and the stack of alternating channel layers and sacrificial layers, forming a bottom dielectric layer in the metal gate cavities and in the bottom cavity, selectively removing the bottom dielectric layer within the bottom cavity, filling the bottom cavity with dielectric material that has etch selectivity from the bottom dielectric layer, and selectively removing the bottom dielectric layers to the dielectric material, and opening the metal gate cavities.

Embodiments of the present disclosure further provide a semiconductor structure forming a portion of a gate-all-around field-effect transistor (GAA FET). The semiconductor structure includes fin-shaped columns on a substrate, each of the fin-shaped columns comprising a self-aligned bottom dielectric isolation (SA-BDI) on the substrate and a stack of alternating channel layers and replacement-metal-gate (RMG) stacks over the SA-BDI, wherein the fin-shaped columns are isolated from one another by a shallow trench isolation (STI), and each of the RMG stacks comprises a metal gate and a gate dielectric layer surrounding the metal gate, and a source/drain (S/D) epitaxial (epi) layer extending through each of the fin-shaped columns into the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic top-view of a multi-chamber processing system, according to one or more embodiments of the present disclosure.

FIGS. 2A and 2A′ are a cross-sectional view and a bottom view of a portion of a semiconductor structure that may form a gate-all-around field-effect transistor (GAA FET), according to one or more embodiments of the present structure. FIGS. 2B, 2C, 2D, and 2E are cross-sectional views of a portion of a semiconductor structure that may form a gate-all-around field-effect transistor (GAA FET), according to one or more embodiments of the present structure.

FIGS. 3A and 3B depict a process flow diagram of a method of forming a self-aligned bottom dielectric isolation (SA-BDI) in a semiconductor structure according to one embodiment.

FIGS. 4A, 4B, 4C, 4D, 4E, 4F, 4G, 4H, 4I, and 4J are cross-sectional views of a portion of a semiconductor structure corresponding to various states of the method of FIGS. 3A and 3B. FIGS. 4A′, 4B′, 4C′, 4D′, 4E′, 4F′, 4G′, 4H′, 4I′, and 4J′ are top-views of a portion of a semiconductor structure corresponding to various states of the method of FIGS. 3A and 3B.

FIGS. 5A and 5B depict a process flow diagram of a method of forming a self-aligned bottom dielectric isolation (SA-BDI) in a semiconductor structure according to one embodiment.

FIGS. 6A, 6B, 6C, 6D, 6E, 6F, 6G, 6H, 6I, 6J, and 6K are cross-sectional views of a portion of a semiconductor structure corresponding to various states of the method of FIGS. 5A and 5B. FIGS. 6A′, 6B′, 6C′, 6D′, 6E′, 6F′, 6G′, 6H′, 6I′, 6J′, and 6K′ are top-views of a portion of a semiconductor structure corresponding to various states of the method of FIGS. 5A and 5B.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

Back-side power delivery in a gate-all-around field-effect transistor (GAA FET) creates new challenges, such as patterning electrical contact features (back-side contact etch) and forming isolation modules on a back side of a silicon (Si) substrate without impacting performance of transistors on a front side of the substrate. Back-side contact etch to form contact holes through the substrate from the back side may damage a gate dielectric layer (e.g., high-k dielectric material) surrounding a metal gate on the front side, when there is a misalignment during the contact etch, as the remainder of the substrate within the contact holes needs to be removed for forming isolation modules in the contact holes. Damage on the gate dielectric layer may lead to gate leakage and threshold voltage shift, degrading electrical performance of the GAA device.

A conventional two dimensional (2D) planer bottom dielectric isolation (BDI) at the bottom of nanosheet channels (both in n-type metal-oxide semiconductor (n-MOS) and p-type MOS (p-MOS) devices) may cause defective and non-uniform source/drain (S/D) epitaxial (epi) growth, leading to loss of channel stress in p-MOS devices and deactivation of n-MOS dopants. These defective source/drain epi layers, formed on the BDI, further degrade electrical performance of the GAA device.

Thus, the embodiments described herein provide methods for forming a portion of a gate-all-around field-effect transistor (GAA FET), in which an S/D epi layer and a self-aligned bottom dielectric isolation (SA-BDI) are formed first on a front side of the substrate, prior to the back-side contact etch and formation of isolation modules on a back side of the substrate.

The SA-BDI may protect the gate dielectric layer during the back-side contact etch, even with misalignment during the back-side contact etch. The SA-BDI may also protect extension regions around an S/D epi layer without inner spacers. Thus, a junction leakage and a threshold voltage shift caused by damage on a gate dielectric layer may be suppressed. The S/D epi layer is grown on surfaces (e.g., silicon (Si) or silicon germanium (SiGe)) of an S/D recess through the channel layers, instead of a BDI (e.g., dielectric material), and thus may have higher quality.

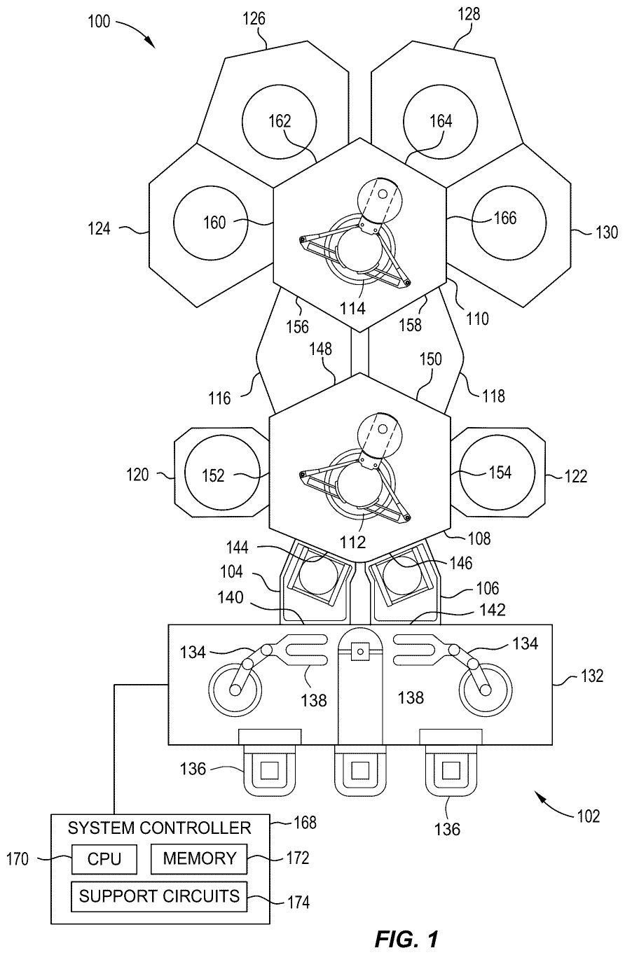

FIG. 1 is a schematic top-view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing etch processes, the processing chamber 122 can be capable of performing cleaning processes, the processing chamber 124 can be capable of performing selective removal processes, the processing chamber 126 can be capable of performing chemical vapor deposition (CVD) deposition processes, and the processing chambers 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126 may be a W×Z™ chamber available from Applied Materials of Santa Clara, Calif. The processing chamber 128, or 130 may be a Centura™ Epi chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

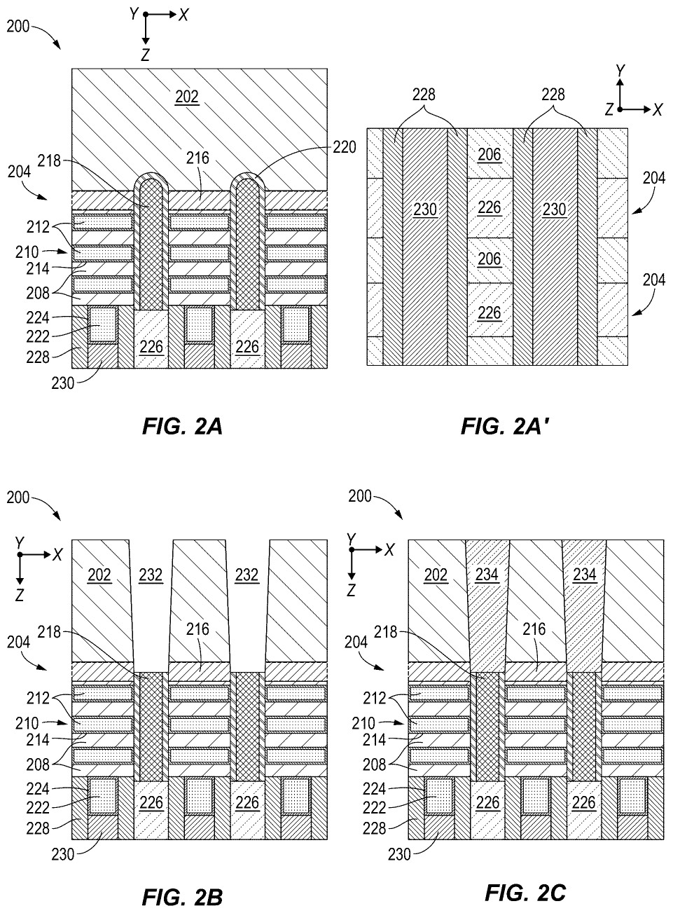

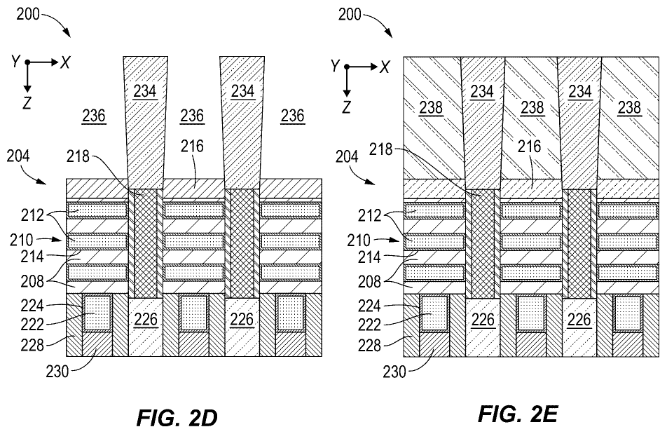

FIGS. 2A and 2A′ are a cross-sectional view and a bottom view of a portion of a semiconductor structure 200 that may form a gate-all-around field-effect transistor (GAA FET), according to one or more embodiments of the present structure. The semiconductor structure 200 is formed on a substrate 202 and a back side of the semiconductor structure 200 is shown upwards in FIG. 2A.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100>, Si<110>, or Si<111>), silicon oxide, strained silicon, silicon germanium, doped or undoped polycrystalline silicon, doped or undoped silicon wafers and patterned or non-patterned wafers, silicon on insulator (SOI), carbon doped silicon oxides, silicon nitride, doped silicon, germanium, gallium arsenide, glass, or sapphire.

As shown in FIGS. 2A and 2A′, the semiconductor structure 200 includes fin-shaped columns 204 extending in the X direction, isolated from adjacent fin-shaped columns 204 by a shallow trench isolation (STI) 206. Each fin-shaped column 204 includes a stack of alternating channel layers 208 and replacement-metal-gate (RMG) stacks 210. Each of the RMG stacks 210 includes a metal gate 212 and a gate dielectric layer 214 surrounding the metal gate 212. Each fin-shaped column 204 further includes a self-aligned bottom dielectric isolation (SA-BDI) 216 on the stack of the alternating channel layers 208 and RMG stacks 210, to protect the RMG stack 210 during a substrate etch from the back side of the semiconductor structure 200.

The STI 206 may be formed of silicon oxide (SiO₂). The channel layers 208 may be formed of silicon (Si), germanium (Ge), silicon germanium (SiGe), or indium gallium zinc oxide (IGZO). The metal gate 212 may be formed of tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof. The gate dielectric layer 214 may be formed of high-k dielectric material, such as hafnium oxides (HfO₂), hafnium zirconium oxide (HfZrO₂), and aluminum oxide (Al₂O₃).

The semiconductor structure 200 further includes a source/drain (S/D) epitaxial (epi) layer 218, via which the channel layers 208 are electrically connected to an S/D contact (not shown). Each S/D epi layer 218 extends through the fin-shaped column 204 and may be interfaced with an extension region 220.

The S/D epi layer 218 may be formed of epitaxially grown silicon (Si) or silicon germanium (SiGe) with a ratio of germanium (Ge) ranging between 10% and 65%, doped with p-type dopants such as boron (B) or gallium (Ga), or n-type dopants such as phosphorus (P), arsenic (As), or antimony (Sb), with a concentration of between about 10¹⁹ cm⁻³ and 5×10²¹ cm⁻³, depending upon the desired conductive characteristic of the S/D epi layer 218.

The SA-BDI 216 be formed of dielectric material, such as silicon oxide (SiO₂), silicon nitride (Si₃N₄), silicon boron carbon nitride (SiBCN), silicon oxy-carbon-nitride (SiOCN), silicon oxycarbide (SiOC), organosilicate glass (SiCOH), or any combination thereof, having a thickness of between about 2 nm and about 20 nm. The extension region 220 may be formed of epitaxially grown silicon (Si) or silicon germanium (SiGe) with a ratio of germanium (Ge) ranging between 0% and 15%, for example, about 10%, lightly doped with p-type dopants such as boron (B) or gallium (Ga), with a concentration of between about 1×10¹⁸ cm−³ and 5×10²⁰ cm⁻³, or silicon (Si) doped with n-type dopants, such as phosphorus (P), arsenic (As), or antimony (Sb), with a concentration of between about 1×10¹⁸ cm−³ and 5×10²⁰ cm⁻³, depending upon the desired conductive characteristic of the extension region 220.

The semiconductor structure 200 further includes metal contacts 222, extending in the Y direction, covered by a gate dielectric layer 224 and isolated from adjacent metal contacts 222 by a front-side ILD 226. The metal contacts 222 are each connectable to a voltage source (not shown). The metal contacts 222 may be each surrounded by a gate spacer 228 on both sides in the X direction and covered by a dielectric layer 230.

The metal contacts 222 may each have critical dimensions of about 10 nm and about 40 nm in the XY plane and spaced from one another by about 20 nm and about 50 nm. The metal contacts 222 may have a depth in the Z direction of between about 10 nm and 100 nm. The metal contacts 222 may be formed of tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof. The front-side ILD 226 may be formed of silicon nitride (Si₃N₄), silicon oxide (SiO₂), silicon oxynitride (SiON), aluminum oxide (Al₂O₃), silicon oxy-carbon-nitride (SiOCN), or any combination thereof, having a thickness of between about 1 nm and about 10 nm, for example, about 4 nm. The gate spacers 228 may be formed of titanium nitride (TiN), tantalum nitride (TaN), titanium aluminum carbide (TiAlC), tungsten nitride (WN), or tungsten (W).

The front-side ILD 226 may be formed of silicon oxide (SiO₂), silicon oxynitride (SiON), aluminum oxide (Al₂O₃), silicon oxy-carbon-nitride (SiOCN), or any combination thereof.

The dielectric layer 230 may be formed of silicon nitride (Si₃N₄), silicon oxynitride (SiON), or silicon oxy-carbon-nitride (SiOCN).

During back-side contact etch to form contact holes 232 within the substrate 202, as shown in FIG. 2B, the gate dielectric layer 214 may be protected by the SA-BDI 216, even with misalignment. Subsequently, the contact holes 232 are each filled with a dielectric layer 234, as shown in FIG. 2C.

During substrate etch to form ILD recesses 236 within the substrate 202 between adjacent dielectric layers 234, as shown in FIG. 2D, the gate dielectric layers 214 surrounding the metal gate 212 are protected. Subsequently, the ILD recesses 236 are each filled with a back-side ILD 238.

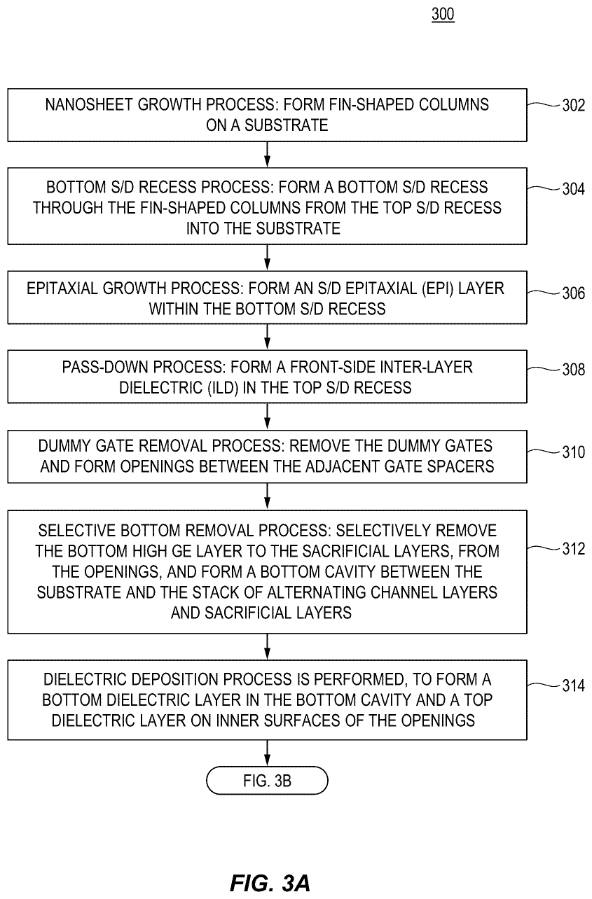

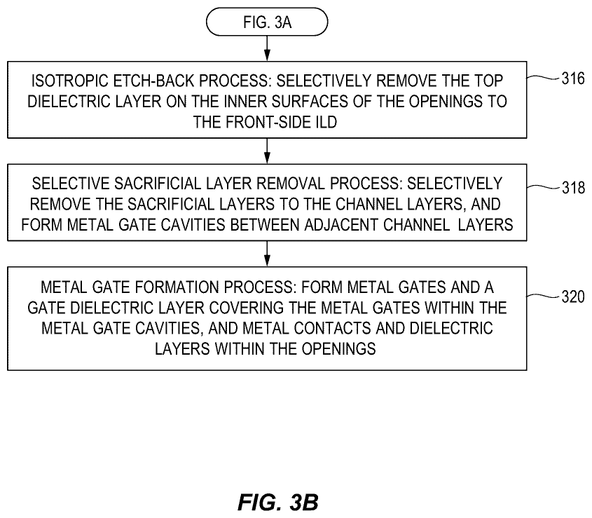

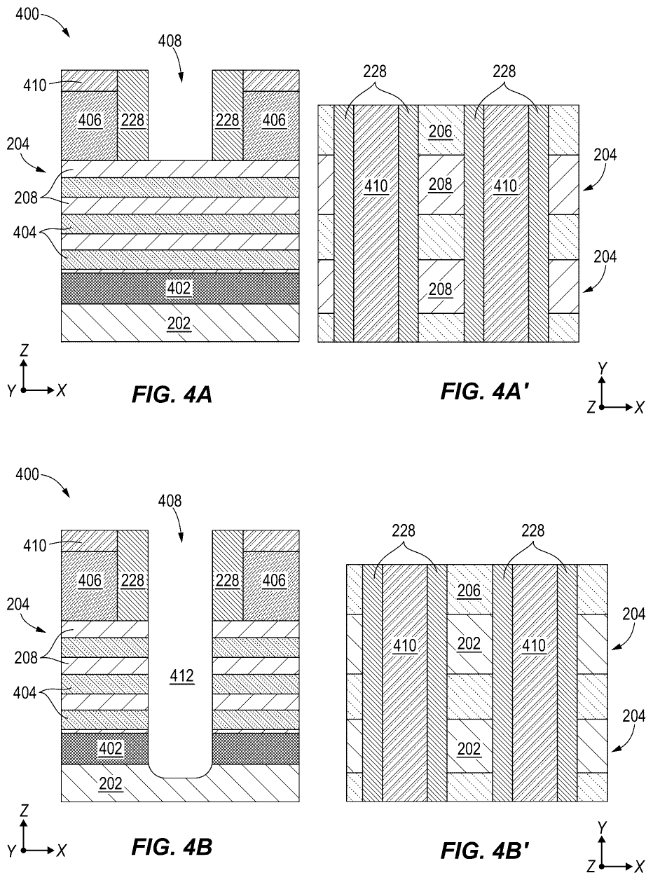

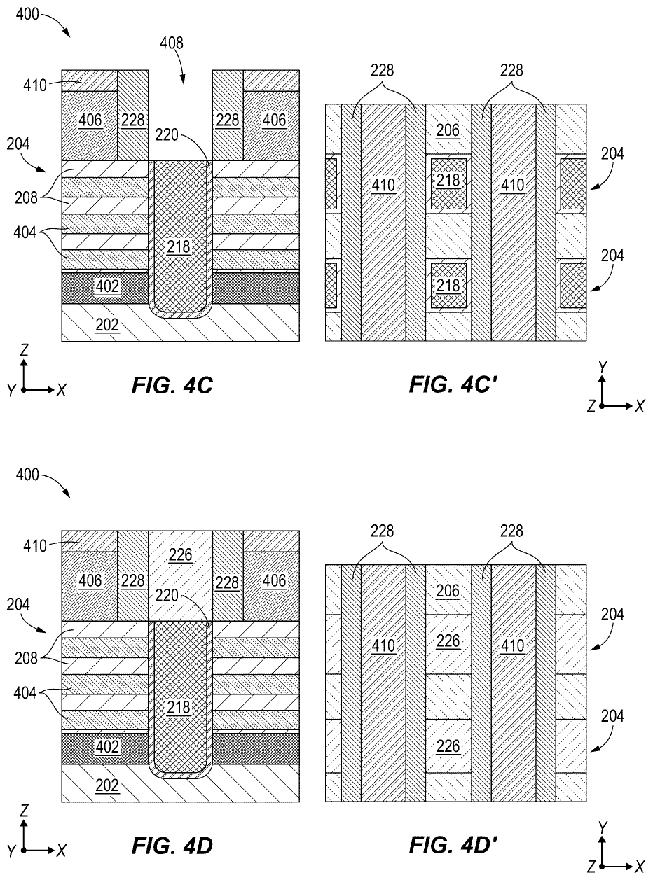

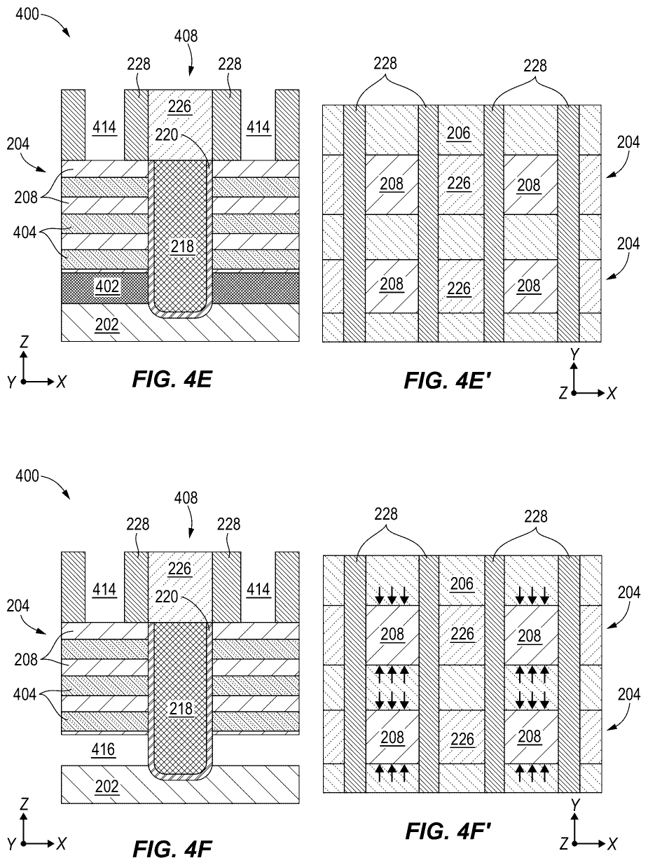

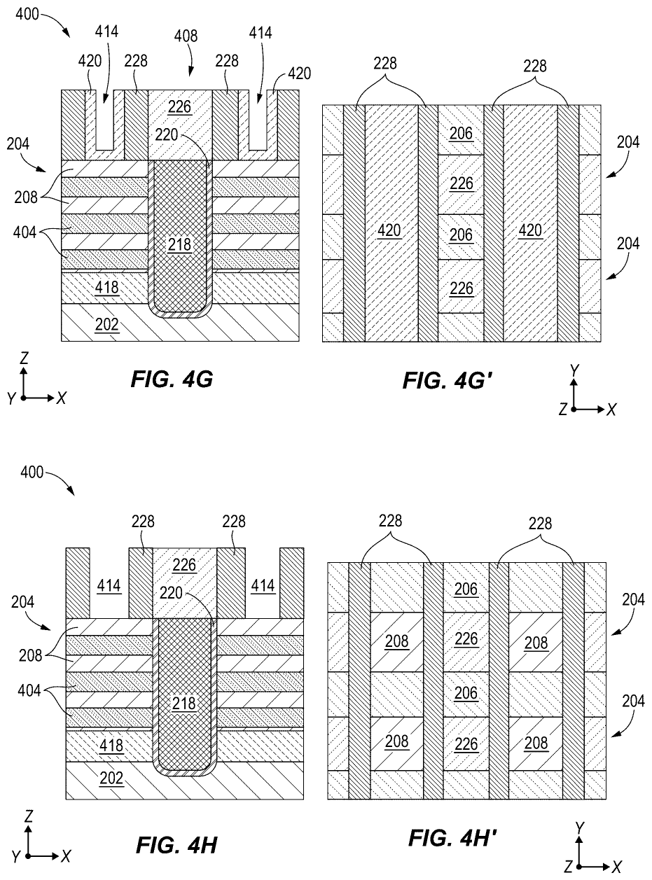

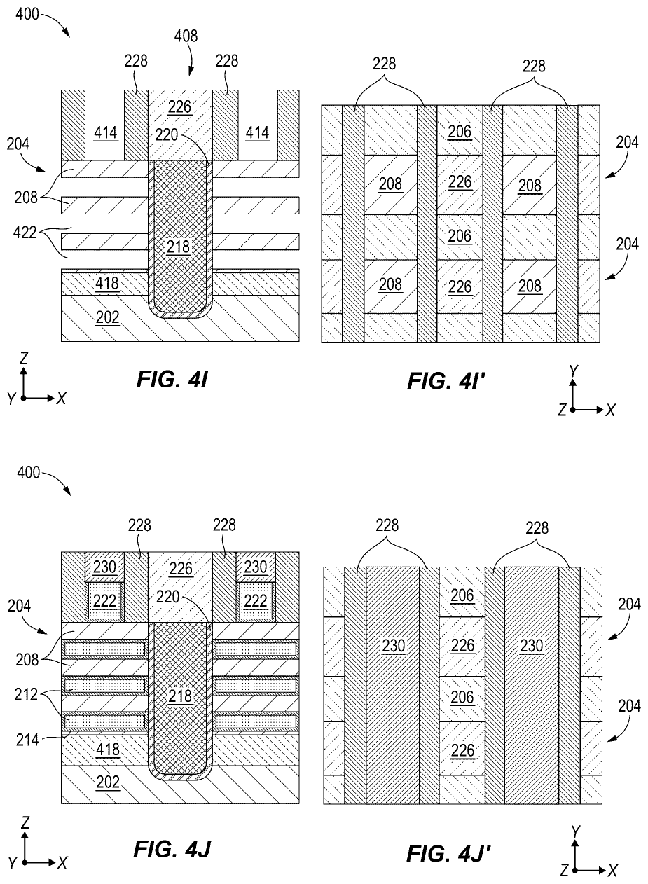

FIGS. 3A and 3B depict a process flow diagram of a method 300 of forming a self-aligned bottom dielectric isolation (SA-BDI) in a semiconductor structure 400 that may be the semiconductor structure 200 forming a portion of a gate-all-around field-effect transistor (GAA FET), according to a first embodiment of the present disclosure. FIGS. 4A, 4B, 4C, 4D, 4E, 4F, 4G, 4H, 4I, and 4J are cross-sectional views of a portion of the semiconductor structure 400 corresponding to various states of the method 300. FIGS. 4A′, 4B′, 4C′, 4D′, 4E′, 4F′, 4G′, 4H′, 4I′, and 4J′ are top-views of a portion of the semiconductor structure 400. It should be understood that FIGS. 4A, 4A′, 4B, 4B′, 4C, 4C′, 4D, 4D′, 4E, 4E′, 4F, 4F′ 4G, 4G′, 4H, 4H′, 4I, 4I′, 4J, and 4J′ illustrate only partial schematic views of the semiconductor structure 400, and the semiconductor structure 400 may contain any number of transistor sections and additional materials having aspects as illustrated in the figures. It should also be noted that although the method illustrated in FIGS. 3A and 3B is described sequentially, other process sequences that include one or more operations that have been omitted and/or added, and/or have been rearranged in another desirable order, fall within the scope of the embodiments of the disclosure provided herein.

In FIGS. 4A, 4B, 4C, 4D, 4E, 4F, 4G, 4H, 4I, and 4J, a front side of the semiconductor structure 400 is shown upwards.

The method 300 begins with block 302, in which a nanosheet growth process is performed to form fin-shaped columns 204 on a substrate 202, as shown in FIGS. 4A and 4A′. The fin-shaped columns 204 extend in the X direction and are isolated from adjacent fin-shaped columns 204 in the Y direction by a STI 206 formed within the substrate 202. The fin-shaped columns 204 each includes a bottom high germanium (Ge) layer 402 on the substrate 202, and a stack of alternating channel layers 208 and sacrificial layers 404 over the bottom high Ge layer 402 in the Z direction. The fin-shaped columns 204 may be formed by epitaxially growing the bottom high Ge layer 402 and the stack of alternating channel layers 208 and sacrificial layers 404 on the substrate 202, and patterning the bottom high Ge layer 402 and the stack of alternating channel layers 208 and sacrificial layers 404. The sacrificial layers 404 are to be replaced with metal gates.

Dummy gates 406 and gate spacers 228 covering the dummy gates 406, extending in the Y direction, are further formed over the fin-shaped columns 204 in the Z direction. A top source/drain (S/D) recess 408 is formed within the gate spacers 228.

As shown, the fin-shaped columns 204 each include three pairs of the channel layers 208 and the sacrificial layers 404. However, in some embodiments, the fin-shaped columns 204 each include between 3 and 8 pairs of the channel layers 208 and the sacrificial layers 404.

The fin-shaped columns 204 may each have a width in the Y direction of between about 6 nm and about 200 nm. A pitch between adjacent dummy gates 406 in the X direction may be between about 30 nm and about 80 nm.

The channel layers 208 may be formed of silicon (Si), germanium (Ge), silicon germanium (SiGe), or indium gallium zinc oxide (IGZO), each having a thickness of between about 3 nm and about 13 nm, for example, about 8 nm. The sacrificial layers 404 may be formed of silicon germanium (SiGe) with a ratio of germanium (Ge) ranging between about 10% and about 25%. The sacrificial layers 404 may each have a thickness of between about 3 nm and about 13 nm.

The bottom high Ge layer 402 may be formed of silicon germanium (SiGe) with a ratio of germanium (Ge) higher than that of the sacrificial layers 404, for example, about 25% or higher, such that the bottom high Ge layer 402 has etch selectivity to the sacrificial layers 404. The bottom high Ge layer 402 may have a thickness of between about 4 nm and about 15 nm.

The STI206 may be formed of silicon oxide (SiO₂). The dummy gates 406 may be formed of polycrystalline silicon (Si) and patterned using a hard mask 410. The gate spacers 228 may be formed of dielectric material, such as silicon nitride (Si₃N₄), silicon oxycarbide (SiOC), silicon oxy-carbon-nitride (SiOCN), or silicon carbon nitride (SiCN).

In block 304, a bottom S/D recess process is performed to form a bottom S/D recess 412 through the fin-shaped columns 204 from the top S/D recess 408 into the substrate 202, as shown in FIGS. 4B and 4B′.

The bottom S/D recess process may include any appropriate lithography and etch processes, such as photolithography and dry anisotropic etching, performed in a processing chamber, such as the processing chamber 120 shown in FIG. 1.

In block 306, an epitaxial growth process is performed to form an S/D epitaxial (epi) layer 218 within the bottom S/D recess 412, as shown in FIGS. 4C and 4C′.

The epitaxial growth process may be an epitaxial deposition process, performed in a processing chamber, such as the processing chamber 126, 128, or 130 shown in FIG. 1.

The S/D epi layer 218 may be formed of epitaxially grown silicon germanium (SiGe), doped with p-type dopants such as boron (B) or gallium (Ga), with a concentration of between about 10²⁰ cm⁻³ and 5×10²¹ cm⁻³, or epitaxially grown silicon (Si), doped with n-type dopants, such as phosphorus (P), arsenic (As), or antimony (Sb), with a concentration of between about 10²⁰ cm⁻³ and 5×10²¹ cm⁻³.

The epitaxial deposition process may use a deposition gas including a silicon-containing precursor, a germanium containing precursor, and a dopant source. The silicon-containing precursor may include silane (SiH₄), disilane (Si₂H₆), tetrasilane (Si₄H₁₀), or a combination thereof. The germanium-containing precursor may include germane (GeH₄), germanium tetrachloride (GeCl₄), and digermane (Ge₂H₆). The dopant source may include, for example, boron (B), or gallium (Ga), phosphorus (P), arsenic (As), or antimony (Sb).

An extension region 220 may be formed on inner surfaces of the bottom S/D recess 412, prior to the epitaxial growth process to form the S/D epi layer 218. The extension region 220 may be formed of epitaxially grown silicon (Si) or silicon germanium (SiGe) with a ratio of germanium (Ge) ranging between 0% and 15%, for example, about 10%, lightly doped with p-type dopants such as boron (B) or gallium (Ga), with a concentration of between about 1×10¹⁸ cm⁻³ and 5×10²⁰ cm⁻³, or silicon (Si) doped with n-type dopants, such as phosphorus (P), arsenic (As), or antimony (Sb), with a concentration of between about 1×10¹⁸ cm⁻³ and 5×10²⁰ cm⁻³, depending upon the desired conductive characteristic of the extension region 220.

In block 308, a pass-down process is performed to form a front-side inter-layer dielectric (ILD) 226 in the top S/D recess 408, as shown in FIGS. 4D and 4D′.

The pass-down process may include a deposition process to fill the top S/D recess 408 with ILD material, and a chemical mechanical polishing (CMP) process to remove over-filled ILD material in the top S/D recess 408 and planarize the front side of the semiconductor structure 400 (shown upwards in FIG. 4D). The deposition process may be any appropriate deposition process, such as chemical vapor deposition (CVD), physical vapor deposition (PVD), or the like performed in a processing chamber, such as the processing chamber 126, 128, or 130 shown in FIG. 1.

The front-side ILD 226 may be formed of silicon oxide (SiO₂), silicon oxynitride (SiON), silicon oxy-carbon-nitride (SiOCN), aluminum oxide (Al₂O₃), or any combination thereof.

In block 310, a dummy gate removal process is performed to remove the dummy gates 406 and form openings 414 between the adjacent gate spacers 228, as shown in FIGS. 4E and 4E′.

The dummy gate removal process may include a CMP process to remove the hard mask 410 to expose the dummy gates 406, and a selective etch process to remove only the dummy gates 406. The selective etch process may be any appropriate etch process, performed in a processing chamber, such as the processing chamber 120 shown in FIG. 1.

In block 312, a selective bottom removal process is performed to selectively remove the bottom high Ge layer 402 to the sacrificial layers 404, from the openings 414, and form a bottom cavity 416 between the substrate 202 and the stack of alternating channel layers 208 and sacrificial layers 404, as shown in FIGS. 4F and 4F′.

The selective bottom removal process may be any appropriate etch process, performed in a processing chamber, such as the processing chamber 120 shown in FIG. 1. Due to the etch selectivity between the bottom high Ge layer 402 (e.g., higher germanium (Ge) concentration) and the sacrificial layers 404 (e.g., lower germanium (Ge) concentration), only the bottom high Ge layer 402 may be removed while the sacrificial layers 404 remain un-etched.

In block 314, a dielectric deposition process is performed, to form a bottom dielectric layer 418 in the bottom cavity 416 and a top dielectric layer 420 on inner surfaces of the openings 414, as shown in FIGS. 4G and 4G′.

The dielectric deposition process may be atomic layer deposition (ALD) process, performed in a processing chamber, such as the processing chamber 126, 128, or 130 shown in FIG. 1.

The bottom dielectric layer 418 and the top dielectric layer 420 may be formed of silicon oxide (SiO₂) or silicon nitride (Si₃N₄).

In block 316, an isotropic etch-back process is performed to selectively remove the top dielectric layer 420 on the inner surfaces of the openings to the front-side ILD 226, as shown in FIGS. 4H and 4H′.

The isotropic etch-back process may be any appropriate etch process, performed in a processing chamber, such as the processing chamber 120 shown in FIG. 1. Due to the etch selectivity between the top dielectric layer 420 and the front-side ILD 226, only the top dielectric layer 420 may be removed while the front-side ILD 226 remains un-etched.

In block 318, a selective sacrificial layer removal process is performed to selectively remove the sacrificial layers 404 to the channel layers 208, and form metal gate cavities 422 between adjacent channel layers 208, as shown in FIGS. 4I and 4I′.

The selective sacrificial layer removal process may be any appropriate etch process, performed in a processing chamber, such as the processing chamber 120 shown in FIG. 1. Due to the etch selectivity between the sacrificial layers 404 (e.g., silicon germanium (SiGe)) and the channel layers 208 (e.g., silicon (Si)), only the sacrificial layers 404 may be removed while the channel layers 208 remain un-etched.

In block 320, a metal gate formation process is performed to form metal gates 212 and a gate dielectric layer 214 covering the metal gates 212 within the metal gate cavities 422, and metal contacts 222 and dielectric layers 230 within the openings 414, as shown in FIGS. 4J and 4J′.

The metal gate formation process may include any appropriate deposition process, such as such as chemical vapor deposition (CVD), physical vapor deposition (PVD), or the like performed in a processing chamber, such as the processing chamber 126, 128, or 130 shown in FIG. 1.

The metal gate 212 may be formed of titanium nitride (TiN), titanium aluminum carbide (TiAlC), or tungsten (W), or may contain other materials such as lanthanum (La), or aluminum (AI). The gate dielectric layer 214 may be formed of high-k dielectric material, such as hafnium oxides (HfO₂), hafnium zirconium oxide (HfZrO₂), or aluminum oxide (Al₂O₃).

The semiconductor structure 400 shown in FIG. 4J corresponds to the semiconductor structure 200 shown in FIG. 2A, where the bottom dielectric layer 418 is the SA-BDI 216.

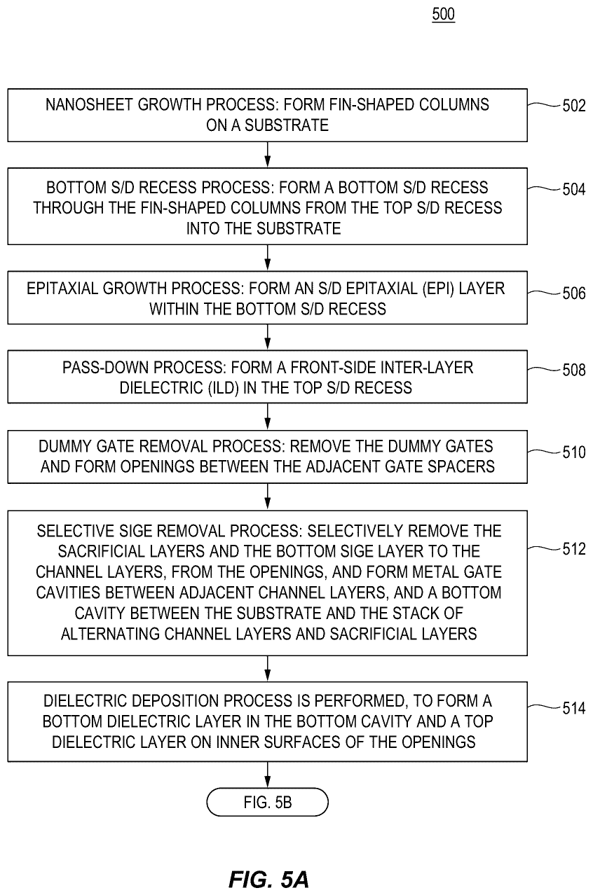

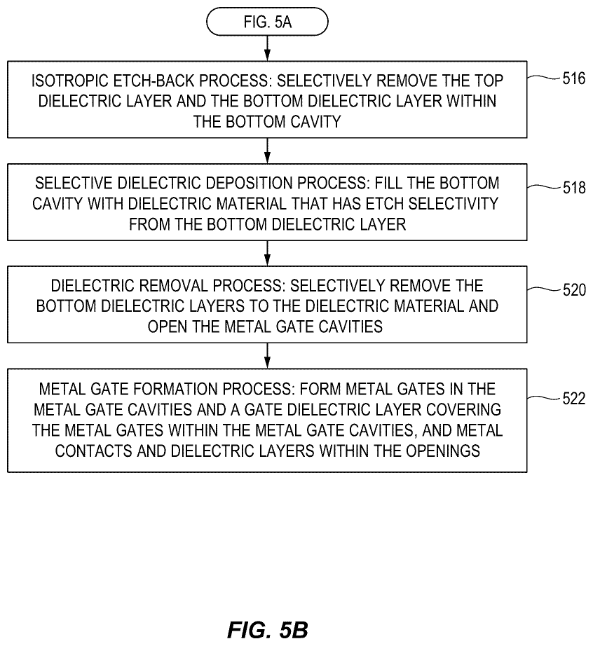

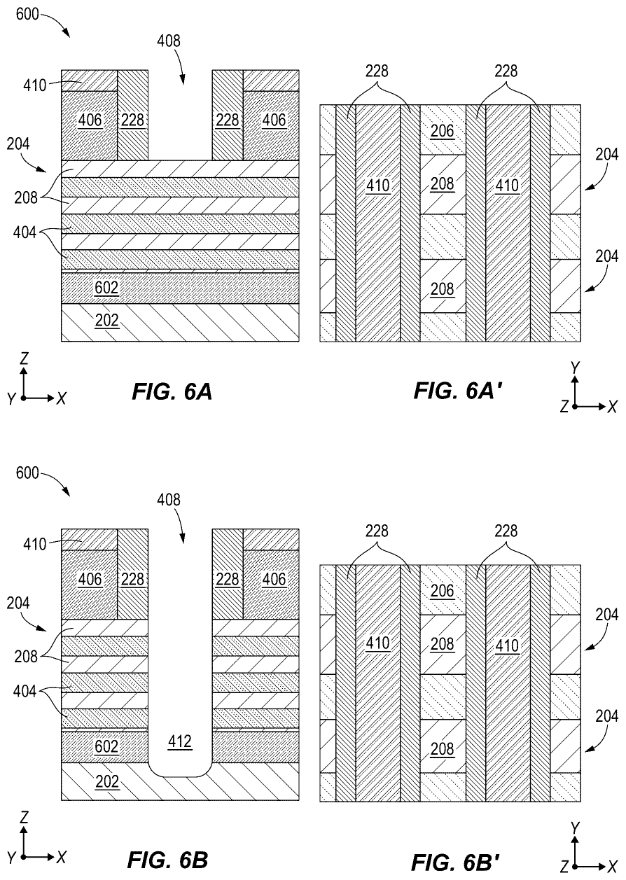

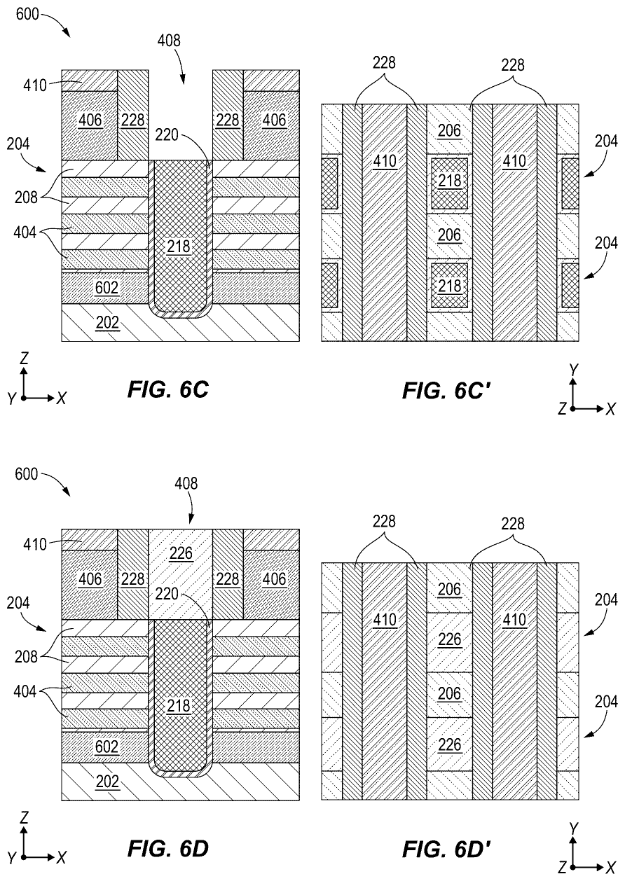

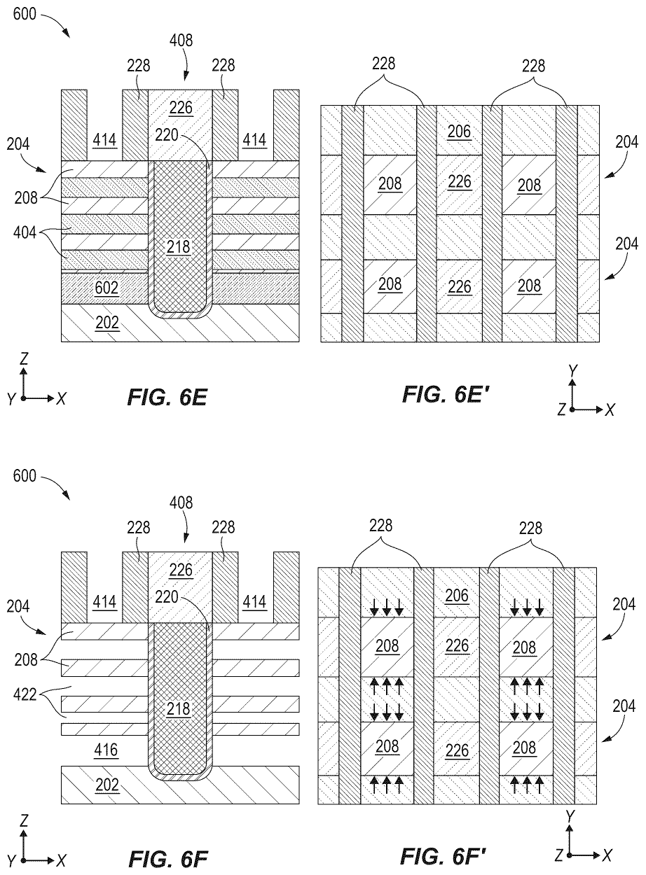

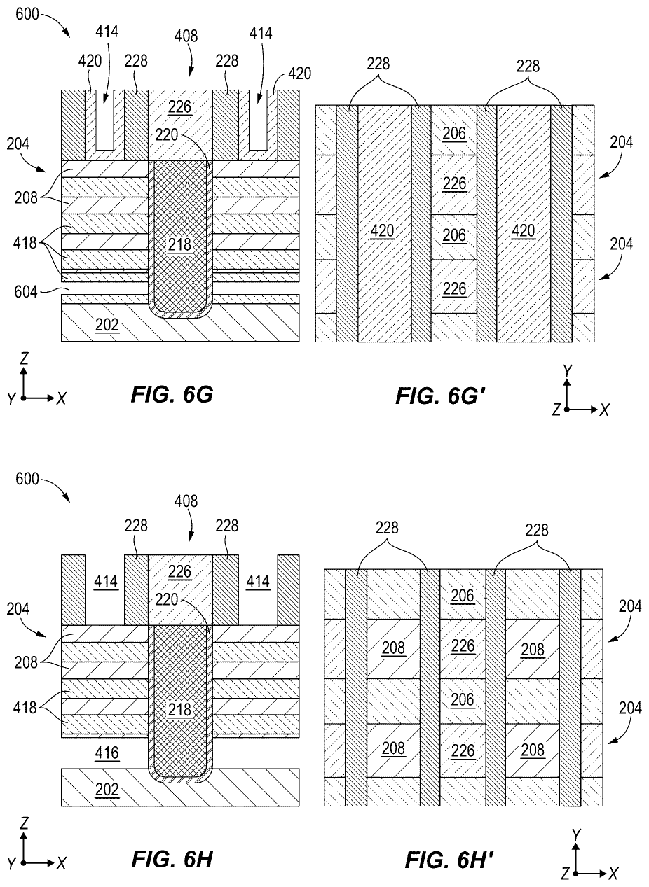

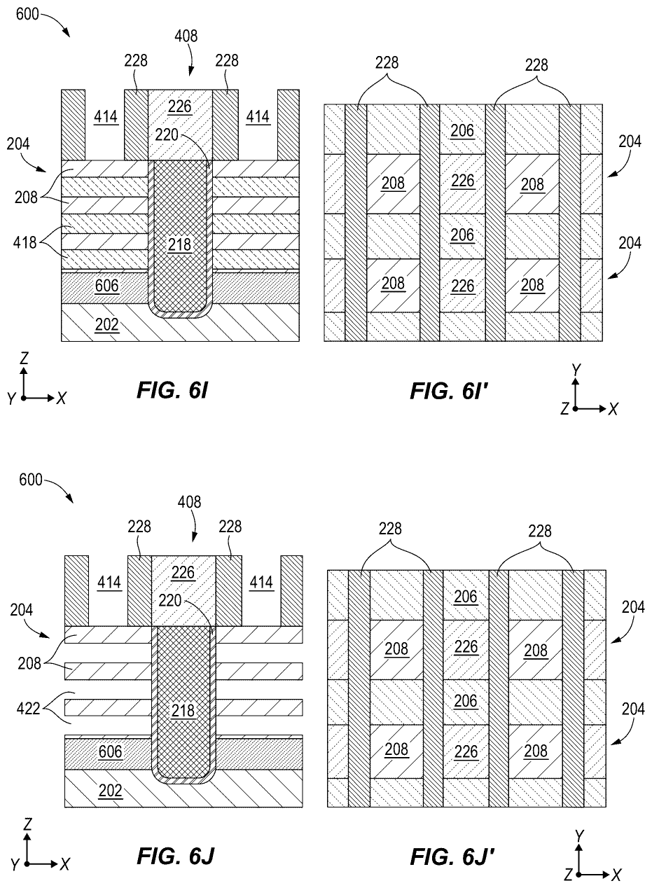

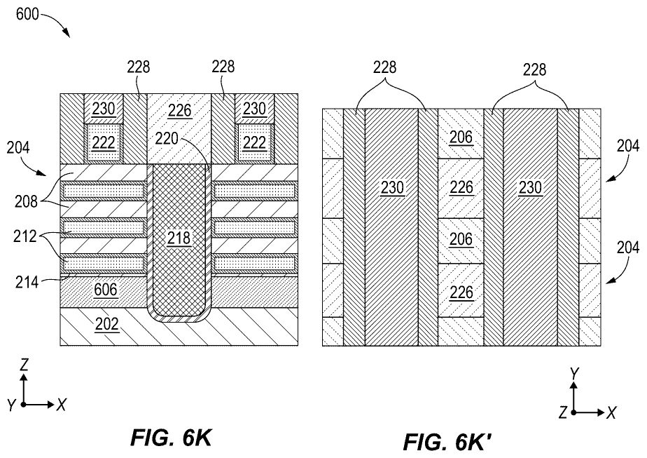

FIGS. 5A and 5B depict a process flow diagram of a method 500 of forming a self-aligned bottom dielectric isolation (SA-BDI) in a semiconductor structure 600 that may be the semiconductor structure 200 forming a portion of a horizontally stacked gate-all-around field-effect transistor (GAA FET) nanosheet structure, according to a second embodiment of the present disclosure. FIGS. 6A, 6B, 6C, 6D, 6E, 6F, 6G, 6H, 6I, 6J, and 6K are cross-sectional views of a portion of the semiconductor structure 600 corresponding to various states of the method 500. FIGS. 6A′, 6B′, 6C′, 6D′, 6E′, 6F′, 6G′, 6H′, 6I′, 6J′, and 6K′ are top-views of a portion of the semiconductor structure 600. It should be understood that FIGS. 6A, 6A′, 6B, 6B′, 6C, 6C′, 6D, 6D′, 6E, 6E′, 6F, 6F′, 6G, 6G′, 6H, 6H′, 6I, 6I′, 6J, 6J′, 6K, and 6K′ illustrate only partial schematic views of the semiconductor structure 600, and the semiconductor structure 600 may contain any number of transistor sections and additional materials having aspects as illustrated in the figures. It should also be noted that although the method illustrated in FIGS. 5A and 5B is described sequentially, other process sequences that include one or more operations that have been omitted and/or added, and/or has been rearranged in another desirable order, fall within the scope of the embodiments of the disclosure provided herein.

In FIGS. 6A, 6B, 6C, 6D, 6E, 6F, 6G, 6H, 6I, 6J, and 6K, a front side of the semiconductor structure 600 is shown upwards.

The method 500 begins with block 502, in which a nanosheet growth process is performed to form fin-shaped columns 204 on a substrate 202, as shown in FIGS. 6A and 6A′. The fin-shaped columns 204 formed in block 502 is the same as fin-shaped columns 204 formed in block 302, except that the bottom high Ge layer 402 is replaced by a bottom silicon germanium (SiGe) layer 602.

The bottom SiGe layer 602 may not have etch selectivity from the sacrificial layers 404, but have a thickness that is thicker than each of the sacrificial layers 404, for example, between about 15 nm and about 30 nm. The sacrificial layers 404 and the bottom SiGe layer 602 may be formed of silicon germanium (SiGe) with a ratio of germanium (Ge) ranging between about 10% and about 50%.

In block 504, a bottom S/D recess process is performed to form a bottom S/D recess 412 through the fin-shaped columns 204 from the top S/D recess 408 into the substrate 202, as shown in FIGS. 6B and 6B′.

The bottom S/D recess process in block 504 is substantially the same as the bottom S/D recess process in block 304.

In block 506, an epitaxial growth process is performed to form an S/D epitaxial (epi) layer 218 and an extension region 220 within the bottom S/D recess 412, as shown in FIGS. 6C and 6C′.

The epitaxial growth process in block 506 is substantially the same as the epitaxial growth process in block 306.

In block 508, a pass-down process is performed to form a front-side inter-layer dielectric (ILD) 226 in the top S/D recess 408, as shown in FIGS. 6D and 6D′.

The pass-down process in block 508 is substantially the same as the pass-down process in block 308.

In block 510, a dummy gate removal process is performed to remove the dummy gate 406 and form openings 414 between the adjacent gate spacers 228, as shown in FIGS. 6E and 6E′.

The dummy gate removal process in block 510 is substantially the same as the dummy gate removal process in block 310.

In block 512, a selective SiGe removal process is performed to selectively remove the sacrificial layers 404 and the bottom SiGe layer 602 to the channel layers 208, from the openings 414, and form metal gate cavities 422 between adjacent channel layers 208, and a bottom cavity 416 between the substrate 202 and the stack of alternating channel layers 208 and sacrificial layers 404, as shown in FIGS. 6F and 6F′.

The selective SiGe removal process may be any appropriate etch process, performed in a processing chamber, such as the processing chamber 120 shown in FIG. 1. Due to the etch selectivity between the sacrificial layers 404 and the bottom SiGe layer 602 (e.g., silicon germanium (SiGe)) and the channel layers 208 (e.g., silicon (Si)), only the sacrificial layers 404 and the bottom SiGe layer 602 may be removed while the channel layers 208 remain un-etched.

In block 514, a dielectric deposition process is performed, to form a bottom dielectric layer 418 in the metal gate cavities 422 and in the bottom cavity 416, and an top dielectric layer 420 on inner surfaces of the openings 414, as shown in FIGS. 6G and 6G′. The metal gate cavities 422 are completely filled with the bottom dielectric layer 418, while the bottom cavity 416 (which is thicker than each of the metal gate cavities 422 in the Z direction) is not completely filled.

The dielectric deposition process in block 514 is substantially the same as the dielectric deposition process in block 314.

In block 516, an isotropic etch-back process is performed to selectively remove the top dielectric layer 420 and the bottom dielectric layer 418 within the bottom cavity 416, as shown in FIGS. 6H and 6H′.

The isotropic etch-back process in block 516 is substantially the same as the isotropic etch-back process in block 316. The top dielectric layer 420 is selectively removed to the front-side ILD 226. The bottom dielectric layer 418 within the bottom cavity 416 is etched from the gap 604, while the bottom dielectric layer 418 within the metal gate cavities 422 remain un-etched.

In block 518, a selective dielectric deposition process is performed to fill the bottom cavity 416 with dielectric material 606 that has etch selectivity from the bottom dielectric layer 418, as shown in FIGS. 6I and 6I′. The dielectric material 606 may be formed of silicon nitride (Si₃N₄). The selective dielectric deposition process may include any appropriate deposition process, such as such as chemical vapor deposition (CVD), physical vapor deposition (PVD), or the like performed in a processing chamber, such as the processing chamber 126, 128, or 130 shown in FIG. 1.

In block 520, a dielectric removal process is performed to selectively remove the bottom dielectric layers 418 to the dielectric material 606 and open the metal gate cavities 422, as shown in FIGS. 6J and 6J′.

The dielectric removal process may be any appropriate etch process, performed in a processing chamber, such as the processing chamber 120, shown in FIG. 1. Due to the etch selectivity between the bottom dielectric layers 418 (e.g., silicon oxide (SiO₂)) and the dielectric material 606 (e.g., silicon nitride (Si₃N₄)).

In block 522, a metal gate formation process is performed to form metal gates 212 in the metal gate cavities 422 and a gate dielectric layer 214 covering the metal gates 212 within the metal gate cavities 422, and metal contacts 222 and dielectric layers 230 within the openings 414, as shown in FIGS. 6K and 6K′.

The metal gate formation process in block 522 is substantially the same as the metal gate formation process in block 320.

The semiconductor structure 600 shown in FIG. 6K corresponds to the semiconductor structure 200 shown in FIG. 2A, where the dielectric material 606 is the SA-BDI 216.

The embodiments described herein provide methods for forming a portion of a gate-all-around field-effect transistor (GAA FET), in which an S/D epi layer and a self-aligned bottom dielectric isolation (SA-BDI) are formed first on a front side of the substrate, prior to the back-side contact etch and formation of isolation modules on a back side of the substrate.

The SA-BDI may protect the gate dielectric layer during the back-side contact etch, even with misalignment during the back-side contact etch. The SA-BDI may also protect extension regions around an S/D epi layer without inner spacers. Thus, a junction leakage and a threshold voltage shift caused by damage on a gate dielectric layer may be suppressed. The S/D epi layer is grown on surfaces (e.g., silicon (Si) or silicon germanium (SiGe)) of an S/D recess through the channel layers, instead of a BDI (e.g., dielectric material), and thus may have higher quality.

While the foregoing is directed to embodiments of the present disclosure, other and further embodiments of the disclosure may be devised without departing from the basic scope thereof, and the scope thereof is determined by the claims that follow.

1. A method of forming a portion of a gate-all-around field-effect transistor (GAA FET), comprising:
forming a bottom source/drain (S/D) recess through fin-shaped columns from a top S/D recess into a substrate, wherein each of the fin-shaped columns comprises a bottom high germanium (Ge) layer on the substrate and a stack of alternating channel layers and sacrificial layers over the bottom high Ge layer;
forming an S/D epitaxial (epi) layer within the bottom S/D recess;
selectively removing the bottom high Ge layer to the sacrificial layers, and forming a bottom cavity between the substrate and the stack of alternating channel layers and sacrificial layers; and
forming a bottom dielectric layer in the bottom cavity.

2. The method of claim 1, wherein:
the channel layers each comprises silicon (Si), germanium (Ge), silicon germanium (SiGe), or indium gallium zinc oxide (IGZO),
the sacrificial layers each comprises silicon germanium (SiGe) with a ratio of germanium (Ge) ranging between 10% and 25%, and
the bottom high Ge layer comprises silicon germanium (SiGe) with a ratio of germanium (Ge) higher than that of the sacrificial layers.

3. The method of claim 1, wherein the S/D epi layer comprises epitaxially grown silicon germanium (SiGe) doped with p-type dopants, or epitaxially grown silicon (Si), doped with n-type dopants.

4. The method of claim 1, wherein the bottom dielectric layer comprises silicon oxide (SiO₂).

5. The method of claim 1, further comprising:
selectively removing the sacrificial layers to the channel layers, and forming metal gate cavities between adjacent channel layers; and
forming metal gates and a gate dielectric layer covering the metal gates within the metal gate cavities.

6. The method of claim 5, wherein:
the metal gates each comprises titanium nitride (TiN), titanium aluminum carbide (TiAlC), or tungsten (W).

7. The method of claim 5, wherein:
the gate dielectric layer comprises hafnium oxides (HfO₂), hafnium zirconium oxide (HfZrO₂), or aluminum oxide (Al₂O₃).

8. A method of forming a portion of a gate-all-around field-effect transistor (GAA FET), comprising:
forming a bottom source/drain (S/D) recess through fin-shaped columns from a top S/D recess into a substrate, wherein each of the fin-shaped column comprises a bottom silicon germanium (SiGe) layer on the substrate and a stack of alternating channel layers and sacrificial layers over the bottom SiGe layer;
forming an S/D epitaxial (epi) layer within the bottom S/D recess;
selectively removing the sacrificial layers and the bottom SiGe layer to the channel layers, and forming metal gate cavities between adjacent channel layers, and a bottom cavity between the substrate and the stack of alternating channel layers and sacrificial layers;
forming a bottom dielectric layer in the metal gate cavities and in the bottom cavity;
selectively removing the bottom dielectric layer within the bottom cavity;
filling the bottom cavity with dielectric material that has etch selectivity from the bottom dielectric layer; and
selectively removing the bottom dielectric layers to the dielectric material, and opening the metal gate cavities.

9. The method of claim 8, wherein:
the channel layers each comprises silicon (Si), germanium (Ge), silicon germanium (SiGe), or indium gallium zinc oxide (IGZO),
the sacrificial layers each comprises silicon germanium (SiGe) and have a thickness of between 3 nm and 13 nm, and
the bottom SiGe layer comprises silicon germanium (SiGe) and have a thickness of between 4 nm and 30 nm.

10. The method of claim 8, wherein the S/D epi layer comprises epitaxially grown silicon germanium (SiGe) doped with p-type dopants, or epitaxially grown silicon (Si), doped with n-type dopants.

11. The method of claim 8, wherein the bottom dielectric layer comprises silicon oxide (SiO₂).

12. The method of claim 11, wherein the dielectric material comprises silicon nitride (Si₃N₄).

13. The method of claim 8, further comprising:
forming metal gates and a gate dielectric layer covering the metal gates within the metal gate cavities.

14. The method of claim 13, wherein:
the metal gates each comprises titanium nitride (TiN), titanium aluminum carbide (TiAlC), or tungsten (W), and
the gate dielectric layer comprises hafnium oxides (HfO₂), hafnium zirconium oxide (HfZrO₂), or aluminum oxide (Al₂O₃).

15. A semiconductor structure forming a portion of a gate-all-around field-effect transistor (GAA FET), comprising:
fin-shaped columns on a substrate, each of the fin-shaped columns comprising a self-aligned bottom dielectric isolation (SA-BDI) on the substrate and a stack of alternating channel layers and replacement-metal-gate (RMG) stacks over the SA-BDI, wherein:
the fin-shaped columns are isolated from one another by a shallow trench isolation (STI), and
each of the RMG stacks comprises a metal gate and a gate dielectric layer surrounding the metal gate; and
a source/drain (S/D) epitaxial (epi) layer extending through each of the fin-shaped columns into the substrate.

16. The semiconductor structure of claim 15, wherein the SA-BDI comprises silicon oxide (SiO₂) or silicon nitride (Si₃N₄).

17. The semiconductor structure of claim 15, wherein:
the metal gates each comprise titanium nitride (TiN), titanium aluminum carbide (TiAlC), or tungsten (W).

18. The semiconductor structure of claim 15, wherein:
the gate dielectric layer comprises hafnium oxides (HfO₂), hafnium zirconium oxide (HfZrO₂), or aluminum oxide (Al₂O₃).

19. The semiconductor structure of claim 15, wherein the S/D epi layer comprises epitaxially grown silicon germanium (SiGe) doped with p-type dopants, or epitaxially grown silicon (Si), doped with n-type dopants.

20. The semiconductor structure of claim 15, wherein:
the channel layers comprise silicon (Si), germanium (Ge), silicon germanium (SiGe), or indium gallium zinc oxide (IGZO).
